(19) United States
(12) Patent Application Publication
(10) Pub. No.: US 2011/0165734 A1
(43) Pub. Date: Jul. 7, 2011

(54) MANUFACTURING METHOD OF SEMI-CONDUCTOR CHIP PACKAGE

(75) Inventors: Seung-Woo Han, Seoul (KR); Jea-Hyuck Lee, Anyang-si (KR); Kyu-Sub Kwak, Suwon-si (KR); Kang-Ho Byun, Seoul (KR); Joon-II Kim, Seoul (KR); Duck-Hwan Kim, Gunpo-si (KR); Kyung-Ho Park, Suwon-si (KR); Se-Mi Park, Seoul (KR)

(73) Assignee: Samsung Electronics Co., Ltd.

(21) Appl. No.: 12/985,900

(22) Filed: Jan. 6, 2011

(30) Foreign Application Priority Data
Jan. 6, 2010 (KR) 10-2010-0000745

(51) Int. Cl. H01L 21/56

(52) U.S. Cl. 438/118; 257/E21.502

(57) ABSTRACT

A manufacturing method of a semiconductor chip package includes molding a semiconductor chip and a number of passive devices after arranging on a film the semiconductor chip and the passive devices located in a vacant space around the periphery of the semiconductor chip; removing the film, forming an adhesive layer in a film-removed area, and attaching a conductive layer to the adhesive layer; etching a conductive layer to thereby form a conductive circuit pattern; and providing one or more conductive pads, which electrically connect the conductive circuit pattern to the semiconductor chip and to the passive devices.

### PRIORITY

This application claims priority under 35 U.S.C. §119(a) to an application entitled “Method Of Semi-Conductor Chip Package” filed in the Korean Intellectual Property Office on Jan. 6, 2010, and assigned Serial No. 10-2010-0000745, the contents of which are incorporated herein by reference.

### BACKGROUND OF THE INVENTION

1. Field of the Invention

The present invention relates generally to a manufacturing method of a semiconductor chip package including an active device and a passive device, and more particularly, to a manufacturing method of a semiconductor chip package, which is capable of high-density mounting with the goal of manufacturing a light, thin, and small package.

2. Description of the Related Art

As popular portable terminals gradually become smaller and more slim, electronic parts used in this portable terminal must also become smaller and more slim. In order to meet this requirement, various forms of the semiconductor chip packages have been developed.

Generally, the semiconductor chip package includes a synthetic resin molding which protects a semiconductor chip having a fine circuit formed thereon and allows the semiconductor chip to be mounted on a Printed Circuit Board (PCB). The semiconductor chip package includes a structure such that electrodes of the semiconductor chip are electrically connected to the PCB having solder balls formed thereon by means of wires for the purpose of electrical connection with an outside device.

In order to conform to the current trend pursuing smaller and more slim portable terminals, semiconductor chip package techniques are being developed toward high integration. One of such semiconductor chip package techniques is the Ball Grid Array (BGA). The BGA includes coupling terminals, which electrically connect the semiconductor chip to the PCB and makes use of solder balls.

As illustrated in FIG. 1, the semiconductor chip package of the prior art includes a semiconductor chip 10, a molding 12, a conductive pad 14, an adhesive portion 15 and solder balls 16. Terminals 12a of the semiconductor chip covered with the molding 12 are connected to the solder balls by the conductive pad 14. The conductive pad 14 is formed to have a pattern by wire rerouting. Specifically, the conductive pad is connected to the semiconductor chip 10 and the conductive pad 14 formed around the semiconductor chip 10 is connected to the semiconductor chip through a circuit pattern (not shown).

However, the semiconductor chip package of the prior art is a one-chip type semiconductor package and has limited ability to decrease the mounting space. Specifically, in the semiconductor chip package of the prior art, an active device is arranged at a center and then wires are rerouted around the semiconductor chip thereby enlarging a ball map. Accordingly, vacant space around the periphery of the one-chip and empty space allowing wire-rerouting thereby lower the availability of the mounting space.

### SUMMARY OF THE INVENTION

Accordingly, the present invention has been made to solve the above-mentioned problems occurring in the prior art. The present invention provides a manufacturing method of a semiconductor chip package, which improves the availability of a mounting space in a semiconductor chip package by including an active device and passive devices in a vacant space around a periphery of the active device, and which improves the performance of parts by wire-rerouting and by rearranging the desired active device in the vacant space.

In order to accomplish this object, there is provided a manufacturing method of a semiconductor chip package, the method including molding a semiconductor chip and a plurality of passive devices after arranging on a film the semiconductor chip and the passive devices located in a vacant space around a periphery of the semiconductor chip; removing the film, forming an adhesive layer in a film-removed area, and attaching a conductive layer to the adhesive layer; etching the conductive layer to thereby form a conductive circuit pattern; and providing one or more conductive pads, which electrically connect the conductive circuit pattern to the semiconductor chip and to the passive devices.

### BRIEF DESCRIPTION OF THE DRAWINGS

The above and other aspects, features and advantages of the present invention will be more apparent from the following detailed description taken in conjunction with the accompanying drawings, in which:

FIG. 1 is a sectional view of a semiconductor chip package according to an example of the prior art.

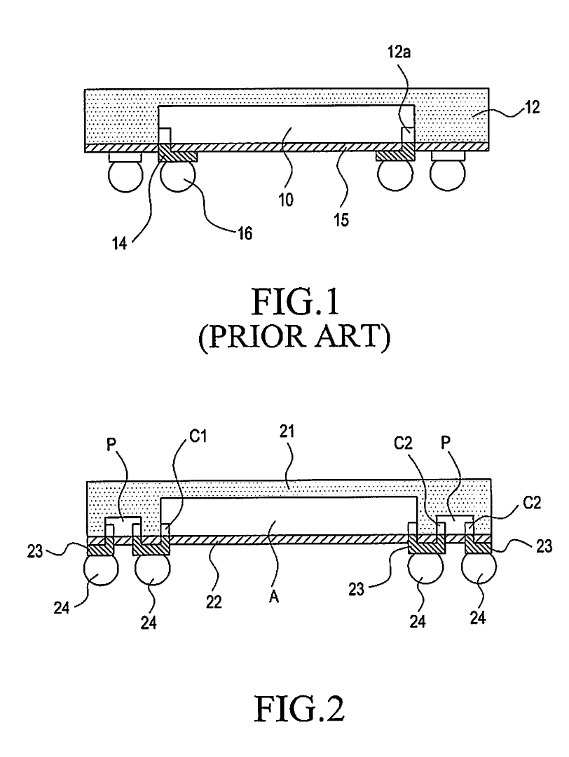

FIG. 2 is a sectional view of a semiconductor chip package according to an embodiment of the present invention.

FIGS. 3a-3f are sectional views illustrating steps of manufacturing the semiconductor chip package according to an embodiment of the present invention.

### DETAILED DESCRIPTION OF EMBODIMENTS OF THE PRESENT INVENTION

Hereinafter, an embodiment of the present invention will be described with reference to the accompanying drawings. In the following description and drawings, the same reference numerals are used to designate the same or similar components, so repetition of descriptions of the same or similar components will be omitted.

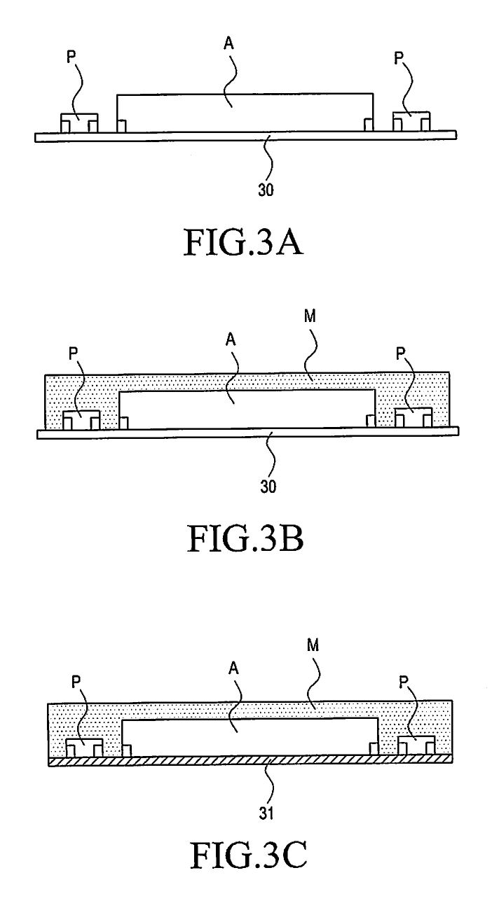

As illustrated in FIG. 2, a semiconductor chip package according to an embodiment of the present invention includes a one-chip type active device A, a plurality of passive devices P, one or more conductive pads 23, a molding 21, adhesive material 22 and solder balls 24. The active device A and the passive devices P are arranged on a film as described bellow, wherein the passive devices P are re-arranged in a vacant space around the periphery of the active device A located at a center. The active device A and the passive devices P are fixed in their positions and are covered with the molding 21 through an Epoxy Molding Compound (EMC) process. Terminals C1 and C2 of the active device A and of the passive devices P are electrically connected to an outside device through the conductive pads 23. The solder balls 24 are attached to the conductive pads 23 to thereby complete the package form, enabling the electrical connection with an outer terminal or an outer PCB. After disposing the active device A at the center, the passive devices P are arranged in the vacant space remaining in the wire-rerouting.

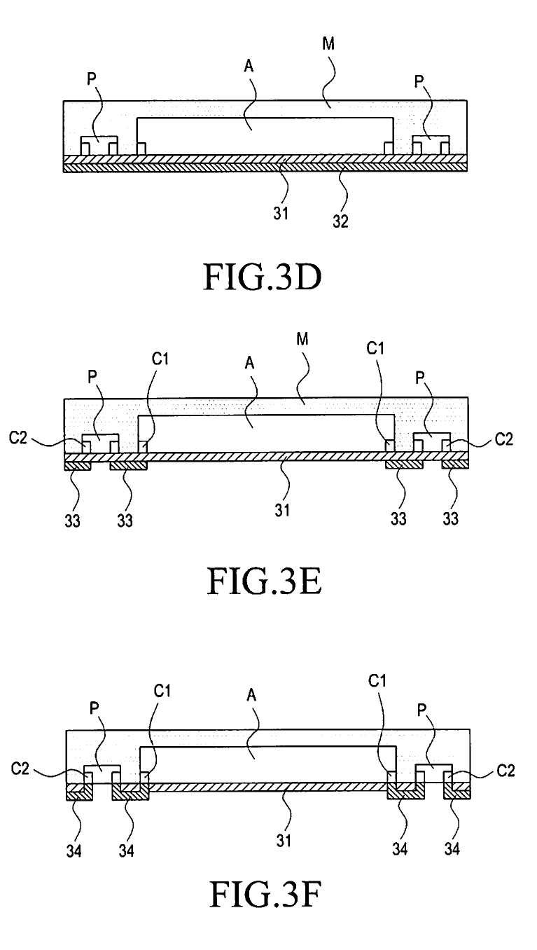

Referring to FIGS. 3a-3f, the manufacturing method of the semi-conductor chip package according to an embodiment of the present invention will be described. The active device described below indicates the one-chip type semiconductor chip.

As illustrated in FIG. 3a, the semiconductor chip A, which is the active device, is arranged on a film 30 and a plurality of the passive devices P are arranged in the vacant space around the periphery of the semiconductor chip A. The passive devices A are disposed at appropriate locations on the film 30 through the re-arrangement. The film 30 is a flexible thin film formed to have an adhesive on one surface thereof, and thus the semiconductor chip A and the passive devices P are arranged on the adhesive surface of the film 30.

As illustrated in FIG. 3b, the semiconductor chip A and the passive devices P arranged on the film 30 are molded with molding M through the EMC process. The semiconductor chip A and the passive devices P are covered with the molding M, and then the molding M is cured to thereby maintain the semiconductor chip A and the passive devices P at determined positions. After the curing of the molding M is finished, the film 30 is removed.

As illustrated in FIG. 3c, adhesive material 31 is an insulator and is applied to the bottom surface of the semiconductor chip A and passive devices A, the positions of which have been fixed by the molding M after removing the film 30. The adhesive material 31 is applied for the purpose of attaching conductive material 32 as described below.

As illustrated in FIG. 3d, the conductive material 32, which is, for example, copper material in the form of a thin film, is attached to the adhesive material 31 forming an adhesive layer on which the semiconductor chip A and the passive devices P are included.

As described in FIG. 3e, an etching process is performed using a mask (not shown) after preparing the semiconductor chip A and the passive devices P, which have a conductive layer formed by attaching the conductive material 32 thereto. One of ordinary skill in the art may readily understand the etching process, in which a circuit pattern is formed using the mask. Here, the mask is made to have a predetermined pattern corresponding to the circuit pattern in consideration of the wire-rerouting process. After finishing the etching process, the conductive layer provides a conductive circuit pattern 33. The conductive circuit pattern 33 is formed to connect the semiconductor chip A and the passive devices P to the outer terminal or the PCB.

After the etching process, through-holes are formed between the semiconductor chip A and the conductive circuit pattern 33 and between the passive devices P and the conductive circuit pattern 33 using a laser. The through-holes are formed to be located between terminals C1 of the semiconductor chip A and the conductive circuit pattern 33 and between terminals C2 of the passive devices P and the conductive circuit pattern 33 in a vertical direction. Specifically, each of the through-holes is formed by emitting the laser to portions of the conductive circuit pattern 33, which are aligned with the terminals C1 of the semiconductor chip A and with the terminals C2 of the passive devices P in the vertical direction. The number of the through-holes corresponds to the number of the terminals C1 and C2 included in the semiconductor chip A and the passive devices P.

After forming the through-holes, the semiconductor chip A and the passive devices P are electrically connected to the conductive circuit pattern 33 through a plating process. After the plating process, one or more conductive pads 34 are provided, which makes the conductive circuit pattern 33 connected to the terminals C1 of the semiconductor chip and to the terminals C2 of the passive devices.

FIG. 3f illustrates a state of the semiconductor chip package after finishing the plating process.

As illustrated in FIG. 3f, the terminals included in the active device, i.e., the semiconductor chip A are electrically connected to the conductive pads 34 located immediately underneath thereof, and the terminals C2 of the passive devices are electrically connected to the conductive pads 34 located immediately underneath thereof, so that the semiconductor chip A is electrically connected to the passive devices P and is capable of being connected to the outer terminal or the PCB. Also, the terminals C2 of the passive devices are electrically connected to the semiconductor chip A through the semiconductor pad 34 and are capable of being connected to the outer terminal or the PCB.

As illustrated in FIG. 2, the semiconductor chip package has the solder balls 24, which are formed on the conductive pads 23 through a posterior process. The forming process of the solder balls 24 is provided for letting the solder balls 24 make contact with the outer terminal, as is well known to one of ordinary skill in the art. Instead of the solder balls, wires are used for making connection with the outer terminal.

As described above, the one-chip type semiconductor chip package of the present invention improves the availability of the mounting space in the semiconductor chip package by arranging a number of the passive devices in the vacant space around the periphery of the one-chip. Particularly, the performance is also improved by re-arranging the desired active device.

Although an embodiment of the present invention has been described for illustrative purposes, those skilled in the art will appreciate that various modifications, additions and substitutions are possible, without departing from the scope and spirit of the invention as disclosed in the accompanying claims.

While the invention has been shown and described with reference to certain embodiments thereof, it will be understood by those skilled in the art that various changes in form and details may be made therein without departing from the spirit and scope of the invention as defined by the appended claims.

What is claimed is:

1. A manufacturing method of a semiconductor chip package, the method comprising:
molding a semiconductor chip and a plurality of passive devices after arranging on a film the semiconductor chip and the passive devices located in a vacant space around a periphery of the semiconductor chip;
removing the film, forming an adhesive layer in a film-removed area, and attaching a conductive layer to the adhesive layer;
etching the conductive layer to thereby form a conductive circuit pattern; and
providing one or more conductive pads, which electrically connect the conductive circuit pattern to the semiconductor chip and to the passive devices.

2. The manufacturing method of Clam 1, wherein etching the conductive layer comprises an etching process performed using a mask with a predetermined pattern formed.

3. The manufacturing method of Clam 1, wherein providing the conductive pads comprises forming through-holes between the semiconductor chip and the conductive circuit pattern and between the passive devices and the conductive circuit pattern using a laser.

4. The manufacturing method of Clam 3, wherein providing the conductive pads comprises electrically connecting the semiconductor chip and the passive devices to the conductive circuit pattern through a plating process after forming the through-holes.

5. The manufacturing method of a Clam 1, further comprising forming solder balls on each of the conductive pads.

6. The manufacturing method of Clam 1, wherein molding the semiconductor chip and the plurality of passive devices comprises curing after molding the semiconductor chip and the passive devices.

7. The manufacturing method of Clam 1, wherein the film has adhesive on a side thereof.

8. The manufacturing method of claim 1, wherein molding the semiconductor chip and the plurality of passive devices comprises arranging the semiconductor chip at a center of the film, and then re-arranging the passive devices around the semiconductor chip.
